(19) United States
(12) Patent Application Publication
(10) Pub. No.: US 2026/0206533 A1
(43) Pub. Date: Jul. 16, 2026

(54) CASSETTE TRANSPORT SYSTEM, METHOD FOR TRANSPORTING CASSETTE USING THE SAME, AND ELECTRONIC DEVICE

(71) Applicant: Samsung Display Co., LTD., Yongin-si (KR)

(72) Inventors: JONGKEUN KIM, Yongin-si (KR); BYEONG-HAN KIM, Yongin-si (KR); TAEKYUN NA, Yongin-si (KR); SUNG SU BAE, Yongin-si (KR); JAE IK BAE, Yongin-si (KR); HYUN-HOO SEO, Yongin-si (KR); HEUNGWON LEE, Yongin-si (KR)

(21) Appl. No.: 19/336,717

(22) Filed: Sep. 23, 2025

(30) Foreign Application Priority Data
Jan. 13, 2025 (KR) 10-2025-0005027

(51) Int. Cl. H10P 72/30; B25J 11/00; H10P 72/10

(52) U.S. Cl. CPC H10P 72/3218; B25J 11/0095; H10P 72/14; H10P 72/3404

(57) ABSTRACT

A cassette transport system includes: a cassette including: support bars on which a substrate is loaded, frames defining an open portion and connected to each other, a filter unit disposed in one frame, a first input pad and a second input pad electrically connected to the filter unit and disposed in one frame, and a regulator disposed in one frame and electrically connected to the first and second input pads, a shelf including support frames on which the cassette is loaded and disposed, and a first output pad disposed on each of the support frames and which wirelessly supplies power to the first input pad by establishing a coupling with the first input pad, and a transport apparatus including a second output pad which transports the cassette and wirelessly supplies power to the second input pad by establishing a coupling with second input pad.

This application claims priority to Korean Patent Application No. 10-2025-0005027, filed on January 13, 2025, and all the benefits accruing therefrom under 35 U.S.C. §119, the content of which in its entirety is herein incorporated by reference.

### BACKGROUND

### 1 Technical Field

Embodiments provide generally to a cassette transport system, a method for transporting a cassette using the same, and an electronic device. More particularly, embodiments relate to the cassette transport system for substrate loading, the method for transporting the cassette using the same, and the electronic device.

### 2 Description of the Related Art

As information technology develops, the importance of display devices, which are communication media between users and information, is being highlighted. Accordingly, the use of display devices such as a liquid crystal display device, an organic light emitting display device, a plasma display device, and the like is increasing.

Meanwhile, a process for manufacturing a display device includes numerous processes such as a process for manufacturing a substrate, a process for manufacturing a cell, a process for manufacturing a module, and the like. As such, the process for manufacturing the display device, which consists of numerous steps, is generally carried out in a clean room. A plurality of substrates which have completed a process by specific processing equipment in the clean room may be first loaded into a cassette and then moved to other processing equipment in the clean room by a transport apparatus.

### SUMMARY

Embodiments provide a cassette transport system for reducing a weight of a cassette.

Embodiments provide a method for transporting a cassette using the cassette transport system.

Embodiments provide an electronic device.

A cassette transport system according to embodiments of the present disclosure includes a cassette including: a plurality of support bars on which a substrate is loaded, a plurality of frames defining an open portion and connected to each other, at least one filter unit disposed on one of the plurality of frames, a first input pad and a second input pad electrically connected to the filter unit and disposed in one of the plurality of frames, and a regulator disposed in one of the plurality of frames and electrically connected to the first input pad and the second input pad, a shelf including a plurality of support frames on which the cassette is loaded and disposed, and a first output pad disposed on each of the plurality of support frames and which wirelessly supplies power to the first input pad by establishing a wireless coupling with the first input pad in case that the cassette is loaded on the first output pad, and a transport apparatus including a second output pad which transports the cassette and wirelessly supplies power to the second input pad by establishing a wireless coupling with the second input pad in case that the cassette is loaded or unloaded by the transport apparatus.

In an embodiment, in case that the cassette is disposed on the plurality of support frames, the first input pad may not directly contact the first output pad.

In an embodiment, in case that the transport apparatus loads or unloads the cassette, the second input pad may not directly contact the second output pad.

In an embodiment, in case that the transport apparatus unloads the cassette from the shelf and the cassette moves away from the shelf, the wireless coupling between the first output pad and the first input pad may be turned off, and the wireless coupling between the second output pad and the second input pad may be maintained, based on a phase difference between a phase of the power applied to the first input pad and a phase of the power applied to the second input pad.

In an embodiment, in case that the cassette is disposed on the plurality of support frames, the first input pad may at least partially overlap the first output pad in a plan view.

In an embodiment, in case that the transport apparatus loads or unloads the cassette, the second input pad may at least partially overlap the second output pad in a plan view.

In an embodiment, the shelf may further include a shelf frame to which the plurality of support frames is connected and which extends in a height direction, and in case that the cassette is disposed on the plurality of support frames, the open portion may face the shelf frame.

In an embodiment, the plurality of support frames of the cassette may include a first frame, a second frame facing the first frame, a third frame connecting the first frame and the second frame, a fourth frame facing the third frame, and a fifth frame connecting the first frame, the second frame, the third frame, and the fourth frame.

In an embodiment, the filter unit may be disposed on the fifth frame.

In an embodiment, the first input pad, the second input pad, and the regulator may be disposed in the third frame.

In an embodiment, a plurality of grooves including a first groove, a second groove, and a third groove may be defined in an outer surface of the third frame, and the first input pad may be disposed in the first groove, the second input pad may be disposed in the second groove, and the regulator may be disposed in the third groove.

In an embodiment, the first groove, the second groove, and the third groove may be adjacent to the fifth frame.

In an embodiment, the first groove may overlap the third groove in a first direction, and the second groove may not overlap the first groove and the third groove in a second direction interesting the first direction.

In an embodiment, the transport apparatus may include a main body capable of moving along a rail and a robot arm, which is connected to the main body to enable to lift and which handles the cassette to load the cassette onto the shelf or unload the cassette from the shelf.

In an embodiment, the second output pad may be disposed on the robot arm in case that the cassette is loaded or unloaded by the transport apparatus.

A method for transporting a cassette according to embodiments of the present disclosure includes: loading the cassette on a shelf including a first output pad by a transport apparatus including a second output pad, where the cassette includes a plurality of support bars on which a substrate is loaded, at least one filter unit, a first input pad and a second input pad electrically connected to the filter unit, and a regulator electrically connected to the first input pad and the second input pad; and unloading the cassette from the shelf by the transport apparatus. In case that the cassette is loaded and disposed onto the shelf, the first output pad may wirelessly supply power to the first input pad by establishing a wireless coupling with the first input pad, and in case that the transport apparatus loads or unloads the cassette, the second output pad may wirelessly supply power to the second input pad by establishing a wireless coupling with the second input pad.

In an embodiment, the cassette may further include a plurality of frames defining an open portion and connected to each other, and the filter unit may be disposed on one of the plurality of frames, and the first input pad, the second input pad, and the regulator may be disposed in another one of the plurality of frames.

In an embodiment, in case that the cassette is disposed on the plurality of support frames, the first input pad may not directly contact the first output pad, and in case that the transport apparatus loads or unloads the cassette, the second input pad may not directly contact the second output pad.

In an embodiment, in case that the transport apparatus unloads the cassette from the shelf and the cassette moves away from the shelf, the wireless coupling between the first output pad and the first input pad may be turned off, and the wireless coupling between the second output pad and the second input pad may be maintained, based on a phase difference between a phase of the power applied to the first input pad and a phase of the power applied to the second input pad.

An electronic device according to embodiments of the present disclosure includes a display device including a substrate which is transported and stored by a cassette transport system and a processor for transmitting an image data signal and an input control signal to the display device. The cassette transport system includes a cassette including: a plurality of support bars on which the substrate is loaded, a plurality of frames defining an open portion and connected to each other, at least one filter unit disposed in one of the plurality of frames, a first input pad and a second input pad electrically connected to the filter unit and disposed in one of the plurality of frames, and a regulator disposed in one of the plurality of frames and electrically connected to the first input pad and the second input pad, a shelf including a plurality of support frames on which the cassette is loaded and disposed, and a first output pad disposed on each of the plurality of support frames and which wirelessly supplies power to the first input pad by establishing a coupling with the first input pad in case that the cassette is loaded, and a transport apparatus including a second output pad which transports the cassette and wirelessly supplies power to the second input pad by establishing a coupling with second input pad in case that the cassette is loaded or unloaded.

In a cassette transport system according to embodiments of the present disclosure, a cassette for loading a substrate may include a first input pad and a second input pad for supplying power to a filter unit, and a regulator electrically connected in common to the first input pad and the second input pad. In case that the cassette is loaded and disposed on a shelf, a first output pad of the shelf may wirelessly supply power to the first input pad of the cassette by establishing a coupling with the first input pad of the cassette. In case that a transport apparatus loads or unloads the cassette, a second output pad of the transport apparatus may wirelessly supply power to the second input pad of the cassette by establishing a coupling with the second input pad of the cassette. Accordingly, the filter unit of the cassette may be continuously operated. In addition, a wireless coupling between an input pad and an output pad may be turned off without a separate controller which controls the power supply by utilizing a phase difference between a power applied to the first input pad and a power applied to the second input pad.

Accordingly, the weight of the cassette may be effectively reduced, the cost of the cassette may be effectively reduced, and the space efficiency of the cassette may be improved.

### BRIEF DESCRIPTION OF THE DRAWINGS

Illustrative, non-limiting embodiments will be more clearly understood from the following detailed description in conjunction with the accompanying drawings.

FIG. 1 is a side view illustrating a cassette transport system according to embodiments of the present disclosure.

FIG. 2 is a side view illustrating airflow due to a filter unit and a ceiling filter unit in the cassette transport system of FIG. 1.

FIG. 3 is a perspective view illustrating a shelf and a cassette of FIG. 1.

FIG. 4 is an enlarged side view of area A of FIG. 1.

FIG. 5 is an enlarged side view of area B of FIG. 1.

FIG. 6 is a perspective view illustrating a cassette of FIG. 1.

FIG. 7 is another perspective view of the cassette of FIG. 6 from a different direction.

FIG. 8 is still another perspective view of the cassette of FIG. 6 from a different direction.

FIG. 9 is a front view of the cassette of FIG. 1 from a different direction.

FIG. 10 is a plan view for explaining a method for a wireless coupling between a robot arm and a cassette of FIG. 1.

FIGS. 11, 12, and 13 are side views for explaining a method for transporting a cassette using the cassette transport system of FIG. 1.

FIG. 14 is a plan view illustrating a cassette transport system according to embodiments of the present disclosure.

FIG. 15 is a cross-sectional view illustrating a display device according to an embodiment.

FIG. 16 is a block diagram illustrating an electronic device according to an embodiment.

### DETAILED DESCRIPTION

It will be understood that when an element is referred to as being “on” another element, it can be directly on the other element or intervening elements may be present therebetween. In contrast, when an element is referred to as being “directly on” another element, there are no intervening elements present.

The terminology used herein is for the purpose of describing particular embodiments only and is not intended to be limiting. As used herein, "a", "an," "the," and “at least one” do not denote a limitation of quantity, and are intended to include both the singular and plural, unless the context clearly indicates otherwise. For example, "an element" has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Hereinafter, a cassette transport system, a method for transporting a cassette using the same, and an electronic device according to embodiments of the present disclosure will be explained in detail with reference to the accompanying drawings. The same reference numerals are used for the same components in the drawings, and redundant descriptions of the same components will be omitted.

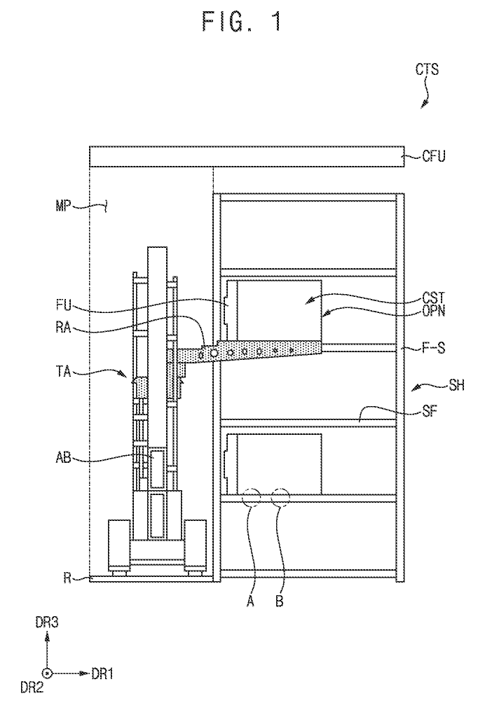

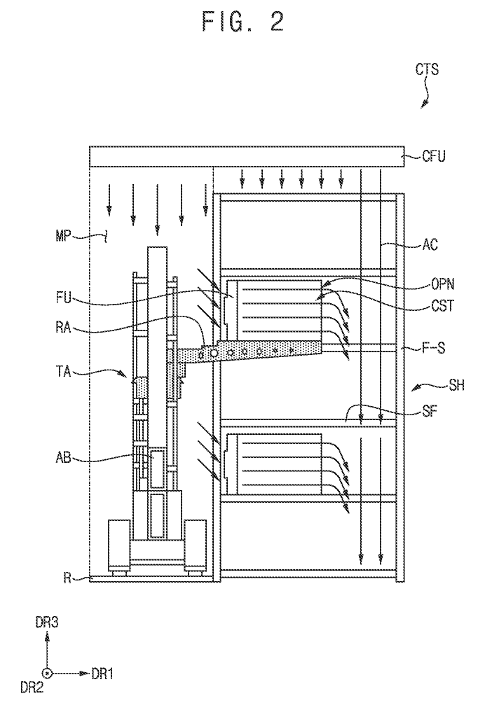

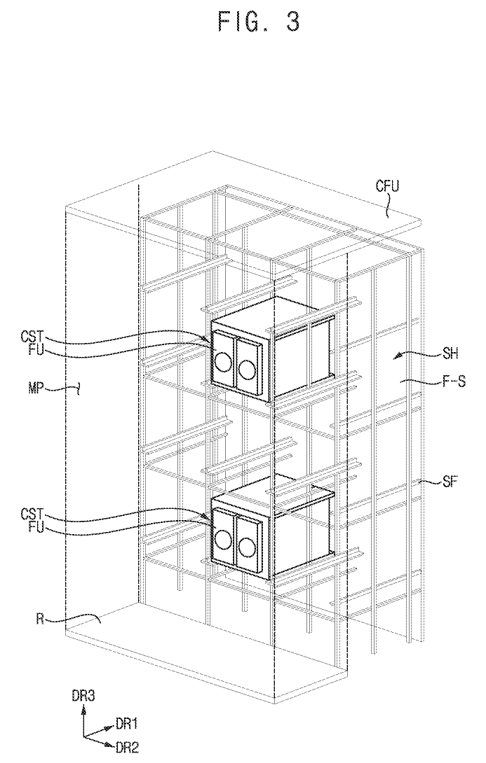

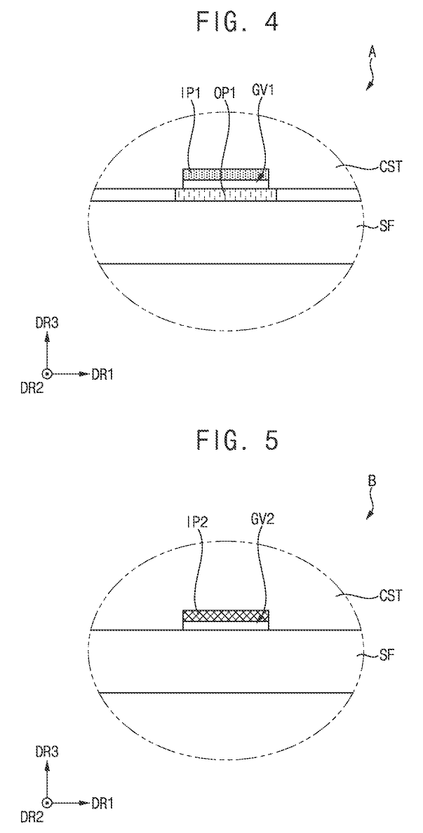

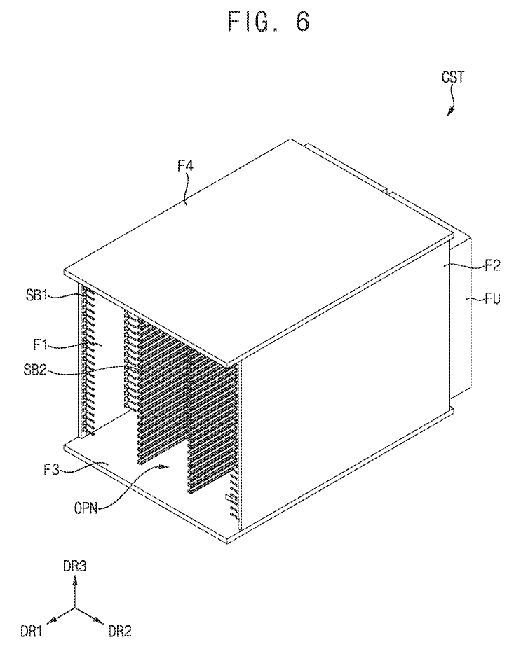

FIG. 1 is a side view illustrating a cassette transport system according to embodiments of the present disclosure. FIG. 2 is a side view illustrating airflow due to a filter unit and a ceiling filter unit in the cassette transport system of FIG. 1. FIG. 3 is a perspective view illustrating a shelf and a cassette of FIG. 1. FIG. 4 is an enlarged side view of area A of FIG. 1. FIG. 5 is an enlarged side view of area B of FIG. 1.

In this specification, a plane may be defined along a first direction DR1 and a second direction DR2 intersecting the first direction DR1. For example, the second direction DR2 may be perpendicular to the first direction DR1. In addition, a third direction DR3 may be perpendicular to the plane.

Referring to FIGS. 1, 2, and 3, a cassette transport system CTS according to embodiments of the present disclosure may include a rail R, a shelf SH, a transport apparatus TA, a cassette CST, and a ceiling filter unit CFU.

For example, the cassette transport system CTS may be disposed in a clean room. The clean room may have a cleanliness class of class 10 or less. However, the embodiments of the present disclosure are not necessarily limited thereto.

The shelf SH may store a plurality of cassettes CST. The shelf SH may include a shelf frame F-S and a plurality of support frames SF spaced apart from each other and connected to the shelf frame F-S.

The shelf frame F-S may extend in a height direction (i.e., the third direction DR3). The plurality of support frames SF may be disposed to be spaced apart along the first direction DR1, the second direction DR2, and the third direction DR3. The cassette CST may be loaded and disposed on the plurality of support frames SF.

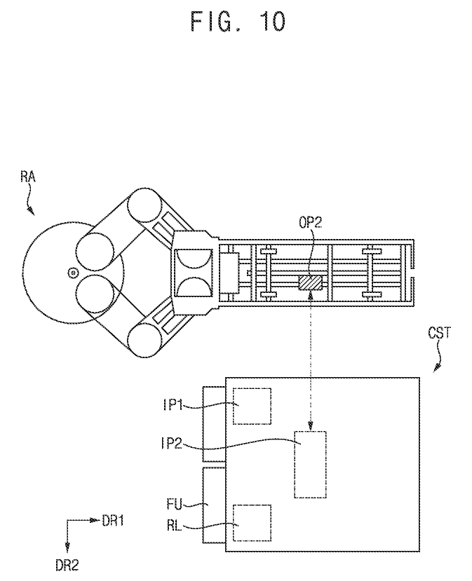

The cassette CST may load and store substrates (e.g., substrate SUB in FIG. 9). For example, the substrate SUB may include a glass substrate for a display device used in a manufacturing process of the display device. However, the embodiments of the present disclosure are not limited thereto, and the substrate SUB may include a silicon wafer used in a semiconductor process.

The cassette CST may define an open portion OPN with one side open. The substrate may be loaded into or unloaded from the cassette CST Through the open portion OPN. For example, the cassette CST may further include an opening/closing door (not shown) detachably connected to the open portion OPN to selectively open and close the open portion OPN. The opening/closing door may be opened in case that loading or unloading the substrate in the cassette CST, and may be closed in case that there is no loading or unloading operation of the substrate. Alternatively, the opening/closing door may be omitted.

The cassette CST may include at least one filter unit FU disposed at one side. The filter unit FU may supply purified air into an internal space of the shelf SH. As the filter unit FU supplies the air into the internal space of the shelf SH, an air current AC flowing in the first direction DR1 may be formed in the internal space of shelf SH (see FIG. 2). For example, the filter unit FU may include an Equipment Fan Filter Unit (EFU), but the embodiments of the present disclosure are not necessarily limited thereto.

In an embodiment, in case that the cassette CST is disposed in the plurality of support frames SF of the shelf SH, the open portion OPN of the cassette CST may face the shelf frame F-S, and the filter unit FU may face the transport apparatus TA. That is, in case that the cassette CST is disposed in the plurality of support frames SF of the shelf SH, the open portion OPN of the cassette CST may not face the transport apparatus TA, and the filter unit FU may not face the shelf frame F-S. Accordingly, the moving particles and eddies flowing in from a moving passage MP may be blocked from contacting the substrate stored in the cassette CST.

Referring to FIGS. 4 and 5, in an embodiment, the shelf SH may further include a first output pad OP1 disposed in each of the plurality of support frames SF in order to supply power to the filter unit FU. That is, the shelf SH may include a plurality of first output pads OP1. Specifically, one first output pad OP1 may be disposed for every two support frames SF supporting one cassette CST. The first output pads OP1 may be disposed to protrude from upper surfaces of each of the support frames SF.

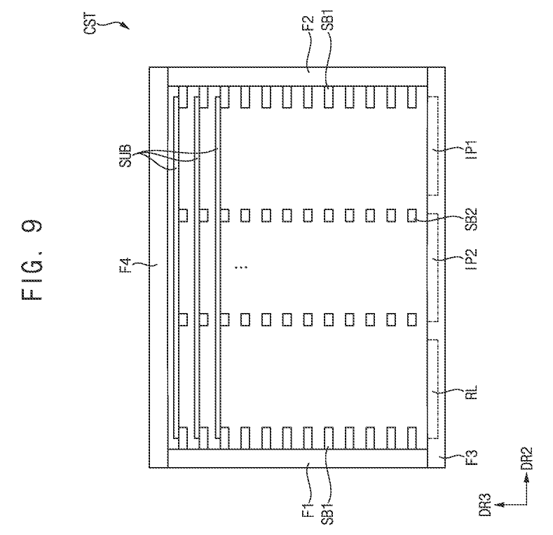

In an embodiment, the cassette CST may further include a first input pad IP1 and a second input pad IP2 electrically connected to the filter unit FU to supply power to the filter unit FU, and a regulator (e.g., a regulator RL in FIGS. 8 and 9) electrically connected to the first and second input pads IP1 and IP2. For example, the first input pad IP1 and the second input pad IP2 may be disposed in a first groove GV1 and a second groove GV2 defined in the cassette CST, respectively. A detailed description of this will be provided later with reference to FIGS. 8 and 9.

The first output pad OP1 may supply power to the first input pad IP1. In an embodiment, in case that the cassette CST is loaded onto the shelf SH (i.e., in case that the cassette CST is disposed in the plurality of support frames SF), the first output pad OP1 may wirelessly supply power to the first input pad IP1 by establishing a coupling with the first input pad IP1. Accordingly, the filter unit FU may be operated by supplying power to the filter unit FU through the first output pad OP1 and the first input pad IP1. That is, in case that the cassette CST is disposed in the plurality of support frames SF, the filter unit FU may be continuously operated.

For example, the first output pad OP1 may wirelessly supply the power to the first input pad IP1 through inductive coupling method, magnetic resonance coupling method, or capacitive coupling method. However, the embodiments of the present disclosure are not necessarily limited thereto.

In an embodiment, in case that the cassette CST is loaded onto the shelf SH (i.e., in case that the cassette CST is disposed in the plurality of support frames SF), the first input pad IP1 may not directly contact the first output pad OP1. That is, in case that the cassette CST is loaded onto the shelf SH, the first input pad IP1 may be spaced apart from the first output pad OP1.

In case that the cassette CST is loaded onto the shelf SH (i.e., in case that the cassette CST is disposed in the plurality of support frames SF), the first input pad IP1 may be adjacent to the first output pad OP1. For example, in case that the cassette CST is loaded onto the shelf SH, the first input pad IP1 may at least partially overlap the first output pad OP1 in the plan view. However, the embodiments of the present disclosure are not necessarily limited thereto. As used herein, the “plan view” is a view in a height direction (i.e., third direction DR3) of the cassette transport system.

Referring again to FIG. 1, the transport apparatus TA may move along the rail R formed on a floor in the second direction DR2 or in a direction opposite the second direction DR2. Specifically, the rail R may be disposed in a movement path MP extending along the second direction DR2, and the transport apparatus TA may move along the rail R inside the movement path MP.

The transport apparatus TA may transport the cassette CST to a desired location. Specifically, the transport apparatus TA may load the cassette CST onto the shelf SH or unload the cassette CST from the shelf SH.

In an embodiment, the transport apparatus TA may include a main body AB which is disposed adjacent to the shelf SH and is movable in a horizontal direction (i.e., the second direction DR2 or a direction opposite second direction DR2) along the rail R, and a robot arm RA which is connected to the main body AB to enable to lift in the third direction DR3 or a direction opposite the third direction DR3, and which handles the cassette CST to load the cassette CST onto the shelf or unload the cassette CST from the shelf SH.

The ceiling filter unit CFU may be disposed on the shelf SH and the transport apparatus TA. The ceiling filter unit CFU may supply purified air to the transport apparatus TA and the shelf SH. As the ceiling filter unit CFU supplies the air to the transport apparatus TA and the shelf SH, an air current AC flowing in a direction opposite to the third direction DR3 may be formed (see FIG. 2).

For example, the ceiling filter unit CFU may include a Fan Filter Unit (FFU). However, the embodiments of the present disclosure are not necessarily limited thereto.

The components of the transport apparatus TA may receive a DC (direct current) voltage, and the filter unit FU of the cassette CST may receive a DC voltage. For example, both components of the transport apparatus TA and the filter unit FU of the cassette CST may receive the same DC voltage (e.g., about 300V).

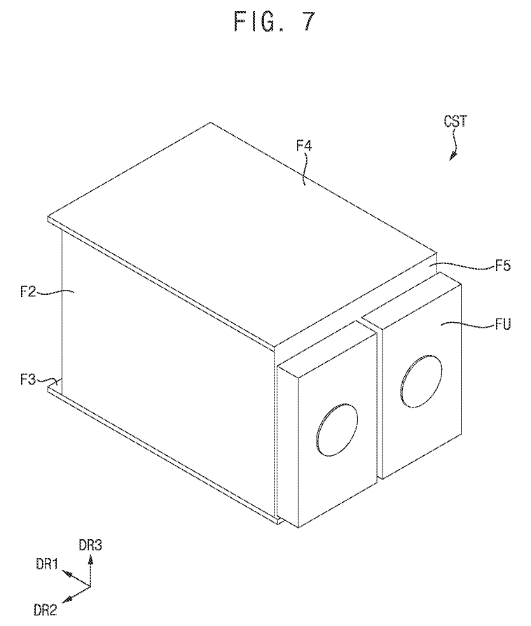

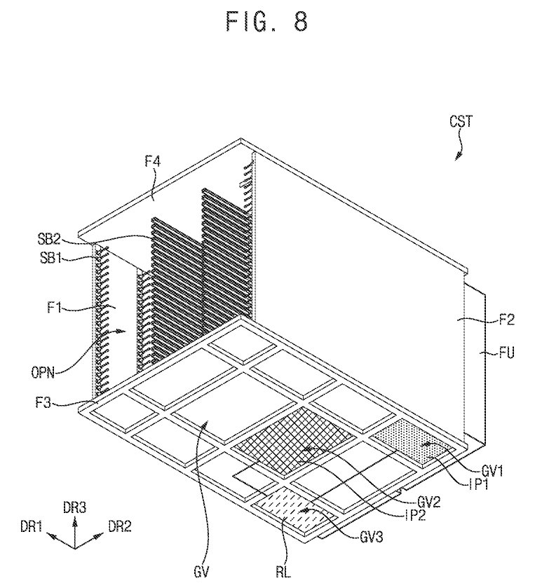

FIG. 6 is a perspective view illustrating a cassette of FIG. 1. FIG. 7 is another perspective view of the cassette of FIG. 6 from a different direction. FIG. 8 is still another perspective view of the cassette of FIG. 6 from a different direction. FIG. 9 is a front view of the cassette of FIG. 1 from a different direction.

Referring to FIGS. 6, 7, 8, and 9, the cassette CST may include a plurality of frames, a plurality of first support bars SB1, a plurality of second support bars SB2, the filter unit FU, the first input pad IP1, the second input pad IP2, and the regulator RL.

The plurality of frames may be connected to each other to define the open portion OPN on one side. For example, the plurality of frames may include a metal material having high mechanical strength. However, the embodiments of the present disclosure are not necessarily limited thereto.

In an embodiment, the plurality of frames may include a first frame F1, a second frame F2, a third frame F3, a fourth frame F4, and a fifth frame F5. The first frame F1 may face the second frame F2. The third frame F3 may connect the first frame F1 and the second frame F2 and may face the fourth frame F4. The fifth frame F5 may connect the first frame F1, the second frame F2, the third frame F3, and the fourth frame F4.

The filter unit FU may be disposed on one of the plurality of frames. In an embodiment, the filter unit FU may be disposed and combined outside the fifth frame F5.

A plurality of substrates SUB may be loaded and stored in the plurality of first support bars SB1 and the plurality of second support bars SB2. The plurality of first support bars SB1 may be coupled to the first frame F1 and the second frame F2 in the inner space of the cassette CST. Each of the plurality of first support bars SB1 may extend along the first direction DR1.

The plurality of second support bars SB2 may be coupled to the fifth frame F5 in the inner space of the cassette CST. Each of the plurality of second support bars SB2 may extend along the first direction DR1. In addition, when viewed from the front, the plurality of second support bars SB2 may be arranged in two rows spaced apart from each other in the third direction DR3 (see FIG. 9).

The first input pad IP1, the second input pad IP2, and the regulator RL may be disposed in one of the plurality of frames. In an embodiment, the first input pad IP1, the second input pad IP2, and the regulator RL may be disposed in an outer surface of the third frame F3. In addition, the first input pad IP1 and the second input pad IP2 may be electrically connected in common to one regulator RL. Accordingly, the weight of the cassette CST may be effectively reduced, the cost of the cassette CST may be effectively reduced, and the space efficiency of the cassette CST may be improved.

However, the embodiments of the present disclosure are not necessarily limited thereto. For example, unlike what is shown in FIG. 8, the first input pad IP1, the second input pad IP2, and the regulator RL may be disposed in an outer surface of the first frame F1, an outer surface of the second frame F2, an outer surface of the fourth frame F4, or an outer surface of the fifth frame F5.

A plurality of grooves may be defined in the outer surface (i.e., a lower surface) of the third frame F3. The plurality of grooves may include a first groove GV1, a second groove GV2, and a third groove GV3. In an embodiment, the first input pad IP1 may be disposed in the first groove GV1, the second input pad IP2 may be disposed in the second groove GV2, and the regulator RL may be disposed in the third groove GV3.

Alternatively, the first input pad IP1 and the second input pad IP2 may be integrated into a single input pad. In this case, the single input pad may be wirelessly coupled to both the first output pad OP1 of FIG. 4 and a second output pad of the transport apparatus TA of FIG. 1.

For example, the first groove GV1, the second groove GV2, and the third groove GV3 may be adjacent to the fifth frame F5. In this case, the first groove GV1 may overlap the third groove GV3 in the second direction DR2, and the second groove GV2 may not overlap the first groove GV1 and the third groove GV3 in the first direction DR1. However, the embodiments of the present disclosure are not necessarily limited thereto.

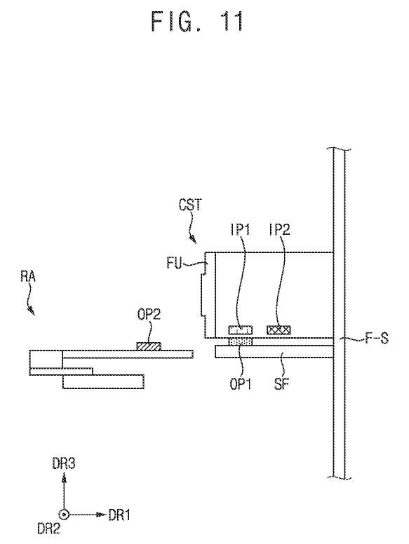

FIG. 10 is a plan view for explaining a method for a wireless coupling between a robot arm and a cassette of FIG. 1.

Referring to FIGS. 1 and 10, as described above, the transport apparatus TA may include the main body AB and the robot arm RA, and the robot arm RA may load the cassette CST onto the shelf SH or unload the cassette CST from the shelf SH.

In an embodiment, the transport apparatus TA may further include a second output pad OP2 disposed on the robot arm RA to supply power to the filter unit FU. The second output pad OP2 may be disposed to protrude from an upper surface of the robot arm RA.

The second output pad OP2 may supply power to the second input pad IP2. In case that the transport apparatus TA loads or unloads the cassette CST, the second output pad OP2 may wirelessly supply power to the second input pad IP2 by establishing a coupling with the second input pad IP2. Accordingly, the filter unit FU may be operated by supplying power to the filter unit FU the second output pad OP2 and the second input pad IP2. That is, in case that the transport apparatus TA loads or unloads the cassette CST, the filter unit FU may be continuously operated.

For example, the second output pad OP2 may wirelessly supply the power to the second input pad (P2 through an inductive coupling method, a magnetic resonance coupling method, or a capacitive coupling method. However, the embodiments of the present disclosure are not necessarily limited thereto.

In an embodiment, in case that the transport apparatus TA loads or unloads the cassette CST, the second output pad OP2 may not directly contact the second input pad IP2. That is, in case that the transport apparatus TA loads or unloads the cassette CST, the second output pad OP2 may be spaced apart from the second input pad IP2.

In case that the transport apparatus TA loads or unloads the cassette CST, the second input pad IP2 may be adjacent to the second output pad OP2. For example, in case that the transport apparatus TA loads or unloads the cassette CST, the second input pad IP2 may at least partially overlap the second output pad OP2 in the plan view. However, the embodiments of the present disclosure are not necessarily limited thereto.

As described above, the first input pad IP1 of the cassette CST may be wirelessly coupled with the first output pad OP1 of the shelf SH, and the second input pad IP2 of the cassette CST may be wirelessly coupled with the second output pad OP2 of the transport apparatus TA. Accordingly, in case that the cassette CST is stored in the shelf SH, since the first input pad IP1 and the first output pad OP1 are wirelessly coupled with each other, the filter unit FU of the cassette CST may be continuously operated to maintain the inside of the cassette CST clean. In addition, in case that the transport apparatus TA transports the cassette CST, since the second input pad IP2 and the second output pad OP2 are wirelessly coupled with each other, the filter unit FU of the cassette CST may be continuously operated to maintain the inside of the cassette CST clean.

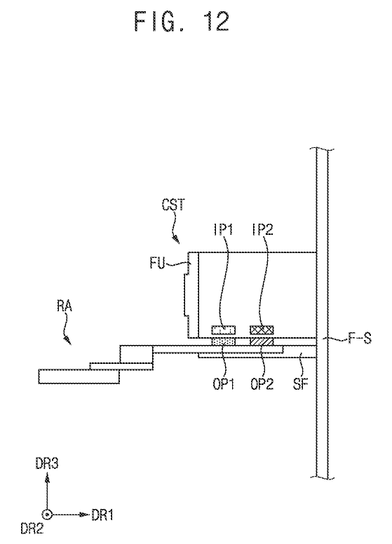

FIGS. 11, 12, and 13 are side views for explaining a method for transporting a cassette using the cassette transport system of FIG. 1. For example, FIGS. 11, 12, and13 are side views for explaining a step of the transport apparatus TA unloading the cassette CST from the shelf SH.

Referring again to FIG. 1, first, the transport apparatus TA may load the cassette CST onto the shelf SH. Specifically, the transport apparatus TA on which the cassette CST is loaded may move along the rail R to set a horizontal position of the transport apparatus TA with respect to the shelf SH. Then, after the robot arm RA is moved upward relative to the main body AB in the height direction (i.e., the third direction DR3), the robot arm RA on which the cassette CST is loaded may be extended so as to be positioned in the plurality of support frames SF of the shelf SH on which the work is to be performed.

During this operation, the second output pad OP2 disposed on the robot arm RA may wirelessly supply power to the second input pad IP2 by establishing a coupling with the second input pad IP2 of the cassette CST. Accordingly, the filter unit FU of the cassette CST may be continuously operated.

Thereafter, the cassette CST loaded onto the robot arm RA may be loaded onto the shelf SH by handling of the robot arm RA. Then, after the robot arm RA is retracted so that the robot arm RA leaves the shelf SH and positioned in the main body AB, the robot arm RA may be moved downward with respect to the main body AB in a direction opposite to the third direction DR3. Then, the transport apparatus TA may move to another place along the rail R.

In an embodiment, in case that the transport apparatus TA loads the cassette CST onto the shelf SH and the robot arm RA moves away from the shelf SH, a wireless coupling between the second output pad OP2 and the second input pad IP2 may be turned off, and a wireless coupling between the first output pad OP1 and the first input pad IP1 may be maintained, based on a phase difference between the power applied to the first input pad IP1 and the power applied to the second input pad IP2. Accordingly, the filter unit FU of the cassette CST may be continuously operated.

Specifically, in case that the transport apparatus TA loads the cassette CST onto the shelf SH and the robot arm RA moves away from the shelf SH, the phase of the power applied to the first input pad IP1 may increase while the phase of the power applied to the second input pad IP2 may decrease, thereby generating the phase difference. In this case, if the phase difference exceeds a preset value, the wireless coupling between the second output pad OP2 and the second input pad IP2 may be turned off, and the wireless coupling between the first output pad OP1 and the first input pad IP1 may be maintained on. Generally, the “phase difference” refers to a temporal deviation between two signals (i.e., powers) even if their amplitudes are the same. In this specification, the “phase difference” refers to a difference between the phase of the power applied to the first input pad IP1 and the phase of the power applied to the second input pad IP2.

Referring to FIGS. 1 and 11, as the transport apparatus TA loads the cassette CST onto the shelf SH, the cassette CST may be loaded and disposed onto the shelf SH. In this case, the first output pad OP1 may wirelessly supply power to the first input pad IP1 by establishing a coupling with the first input pad IP1. Accordingly, the filter unit FU may be continuously operated.

The transport apparatus TA may move to a location adjacent to the shelf SH along the rail R. Then, the transport apparatus TA may unload the cassette CST from the shelf SH. Specifically, the transport apparatus TA may move along the rail R to set the horizontal position of the transport apparatus TA with respect to the shelf SH. Then, the robot arm RA may be moved upward with respect to the main body AB in the height direction (i.e., the third direction DR3).

Referring to FIG. 12, in case that the robot arm RA unloads the cassette CST stored on the shelf SH, the robot arm RA may be extended under the cassette CST stored on the shelf SH.

In case that the transport apparatus TA unloads the cassette CST from the shelf SH through the robot arm RA, the second output pad OP2 may wirelessly supply power to the second input pad IP2 by establishing a coupling with the second input pad IP2. Accordingly, the filter unit FU may be continuously operated.

Referring to FIG. 13, after the transport apparatus TA unloads the cassette CST from the shelf SH, the robot arm RA may be retracted that the robot arm RA leaves from the shelf SH and positioned in the main body AB.

In an embodiment, in case that the transport apparatus TA unloads the cassette CST from the shelf SH and the cassette CST moves away from the shelf SH, the wireless coupling between the first output pad OP1 and the first input pad IP1 may be turned off, and the wireless coupling between the second output pad OP2 and the second input pad IP2 may be maintained, based on the phase difference between the power applied to the first input pad IP1 and the power applied to the second input pad IP2. Accordingly, the filter unit FU of the cassette CST may be continuously operated.

Specifically, in case that the transport apparatus TA unloads the cassette CST from the shelf SH and the cassette CST moves away from the shelf SH, the phase of the power applied to the first input pad IP1 may decrease and the phase of the power applied to the second input pad IP2 may increase, thereby generating the phase difference. In this case, if the phase difference exceeds a preset value, the wireless coupling between the first output pad OP1 and the first input pad IP1 may be turned off, and the wireless coupling between the second output pad OP2 and the second input pad IP2 may be maintained on.

Referring again to FIGS. 1 to 13, in the cassette transport system CTS according to embodiments of the present disclosure, the cassette CST for loading the substrate SUB may include the first input pad IP1 and the second input pad IP2 for supplying power to the filter unit FU, and the regulator RL electrically connected in common to the first input pad IP1 and the second input pad IP2. In case that the cassette CST is loaded and disposed onto the shelf SH, the first output pad OP1 of the shelf SH may wirelessly supply power to the first input pad IP1 of the cassette CST by establishing a coupling with the first input pad IP1 of the cassette CST. In case that the transport apparatus TA loads or unloads the cassette CST, the second output pad OP2 of the transport apparatus TA may wirelessly supply power to the second input pad IP2 of the cassette CST by establishing a coupling with the second input pad IP2 of the cassette CST. Accordingly, the filter unit FU of the cassette CST may be continuously operated. In addition, the wireless coupling between an input pad and an output pad may be turned off without a separate controller which controls the power supply by utilizing the phase difference between the power applied to the first input pad IP1 and the power applied to the second input pad IP2.

Accordingly, the weight of the cassette CST may be effectively reduced, the cost of the cassette CST may be effectively reduced, and the space efficiency of the cassette CST may be improved.

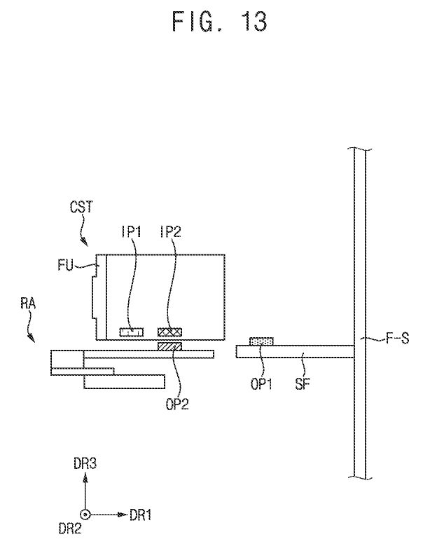

FIG. 14 is a plan view illustrating a cassette transport system according to embodiments of the present disclosure.

Referring to FIGS. 1 and 14, in an embodiment, the cassette transport system CTS may further include a pod PO, a first transport apparatus TA1, and a second transport apparatus TA2.

The pod PO may include a third output pad OP3 for supplying power to the filter unit FU of the cassette CST. The first transport apparatus TA1 may include a first robot arm RA1 and a fourth output pad OP4 disposed on the first robot arm RA1 for supplying power to the filter unit FU. The second transport apparatus TA2 may include a fifth output pad OP5 for supplying power to the filter unit FU.

The transport apparatus TA of FIG. 1 may unload the cassette CST from the shelf SH and lift the robot arm RA on which the cassette CST is loaded in the third direction DR3 (i.e., height direction.). Then, the robot arm RA on which the cassette CST is loaded may be extended toward the pod PO, and the robot arm RA may load the cassette CST into the pod PO.

In case that the cassette CST is loaded and disposed in the pod PO, the third output pad OP3 may wirelessly supply power to the first input pad IP1 by establishing a coupling with the first input pad IP1. Accordingly, the filter unit FU of the cassette CST may be continuously operated.

In case that the cassette CST is loaded onto the pod PO and the robot arm RA of the transport apparatus TA leaves from the pod PO, the wireless coupling between the second output pad OP2 and the second input pad IP2 may be turned off, and the wireless coupling between the third output pad OP3 and the first input pad IP1 may be maintained, based on a phase difference between the power applied to the first input pad IP1 and the power applied to the second input pad IP2. Accordingly, the filter unit FU may be continuously operated.

Specifically, in case that the cassette CST is loaded onto the pod PO and the robot arm RA of the transport apparatus TA leaves from the pod PO, the phase of the power applied to the first input pad IP1 may increase, and the phase of the power applied to the second input pad IP2 may decrease, thereby generating a phase difference. In this case, if the phase difference exceeds a preset value, the wireless coupling between the second output pad OP2 and the second input pad IP2 may be turned off, and the wireless coupling between the third output pad OP3 and the first input pad IP1 may be maintained as on.

The first transport apparatus TA1 may unload the cassette CST from the pod PO. Specifically, the first transport apparatus TA1 may unload the cassette CST by extending the first robot arm RA1 over the pod PO. Then, the first transport apparatus TA1 may retract the first robot arm RA1 to its original position, rotate clockwise, and extend the first robot arm RA1 toward the second transport apparatus TA2. The first robot arm RA1 on which the cassette CST is loaded may load the cassette CST onto the second transport apparatus TA2.

In case that the first transport apparatus TA1 loads or unloads the cassette CST, the fourth output pad OP4 may wirelessly supply power to the second input pad IP2 by establishing a coupling with the second input pad IP2 Accordingly, the filter unit FU may be continuously operated.

In case that the first transport apparatus TA1 unloads the cassette CST from the pod PO and the cassette CST moves away from the pod PO, the wireless coupling between the third output pad OP3 and the first input pad IP1 may be turned off, and the wireless coupling between the fourth output pad OP4 and the second input pad IP2 may be maintained, based on the phase difference between the power applied to the first input pad IP1 and the power applied to the second input pad IP2. Accordingly, the filter unit FU may be continuously operated.

Specifically, in case that the first transport apparatus TA1 unloads the cassette CST from the pod PO and the cassette CST moves away from the pod PO, the phase of the power applied to the first input pad IP1 may decrease, and the phase of the power applied to the second input pad IP2 may increase, thereby generating the phase difference. In this case, if the phase difference exceeds a preset value, the wireless coupling between the third output pad OP3 and the first input pad IP1 may be turned off, and the wireless coupling between the fourth output pad OP4 and the second input pad IP2 may be maintained as on.

In case that the cassette CST is loaded and disposed onto the second transport apparatus TA2 by the first robot arm RA1, the fifth output pad OP5 may wirelessly supply power to the first input pad IP1 by establishing a coupling with the first input pad IP1. Accordingly, the filter unit FU may be continuously operated.

In case that the first transport apparatus TA1 loads the cassette CST onto the second transport apparatus TA2 and the first robot arm RA1 leaves from the second transport apparatus TA2, the wireless coupling between the fourth output pad OP4 and the second input pad IP2 may be turned off, and the wireless coupling between the fifth output pad OP5 and the first input pad IP1 may be maintained, based on the phase difference between the power applied to the first input pad IP1 and the power applied to the second input pad IP2. Accordingly, the filter unit FU may be continuously operated.

Specifically, in case that the first transport apparatus TA1 loads the cassette CST onto the second transport apparatus TA2 and the first robot arm RA1 leaves from the second transport apparatus TA2, the phase of the power applied to the first input pad IP1 may increase, and the phase of the power applied to the second input pad IP2 may decrease, thereby generating the phase difference. In this case, if the phase difference exceeds a preset value, the wireless coupling between the fourth output pad OP4 and the second input pad IP2 may be turned off, and the wireless coupling between the fifth output pad OP5 and the first input pad IP1 may be maintained as on.

The second transport apparatus TA2 on which the cassette CST is loaded may move along a rail R′ to transport the cassette CST to a desired position for a subsequent process.

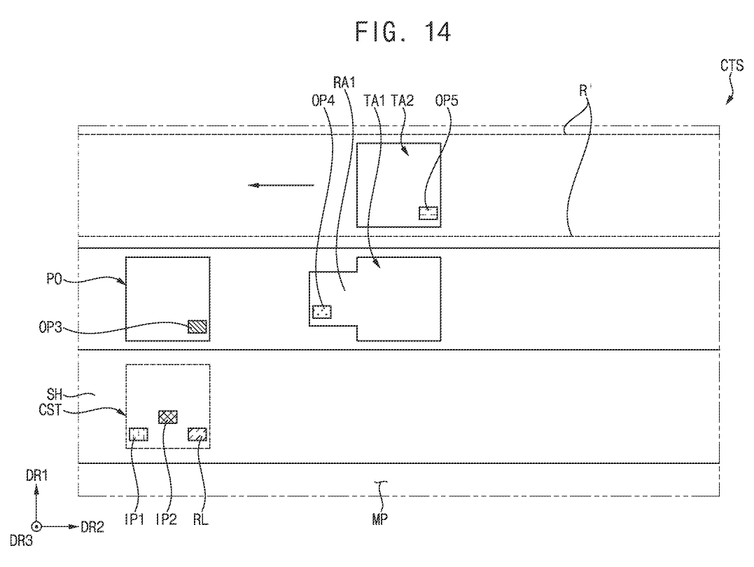

FIG. 15 is a cross-sectional view illustrating a display device according to an embodiment.

Referring to FIG. 15, a display device DD may further include a substrate SUB, a pixel circuit layer PCL, a light-emitting element layer EML, an encapsulation layer ENC, a touch sensor layer TCL, an anti-reflection layer RCL, and a window member WM.

The substrate SUB may be a glass substrate, a metal substrate, or a polymer substrate. In an embodiment, during the manufacturing process of the display device DD, the substrate SUB may be transported and stored by the cassette transport system CTS of FIG. 1.

The pixel circuit layer PCL may be disposed on the substrate SUB. The pixel circuit layer PCL may include an insulating layer, a semiconductor element (e.g., a transistor), a conductive layer, a signal line, and the like. The light-emitting element layer EML may be disposed on the pixel circuit layer PCL. The light-emitting element layer EML may include a light-emitting element which generates light. For example, the light-emitting element may include organic light-emitting materials, inorganic light-emitting materials, organic-inorganic hybrid light-emitting materials, quantum dots, micro-LEDs, or nano-LEDs.

The encapsulation layer ENC may be disposed on the light-emitting element layer EML. The encapsulation layer ENC may protect the light-emitting element layer EML from foreign substances such as moisture and oxygen. For example, the encapsulation layer ENC may include at least one inorganic layer and at least one organic layer.

The touch sensor layer TCL may be disposed on the encapsulation layer ENC. The touch sensor layer TCL may detect external inputs applied from the outside. The external input may be a user input.

The anti-reflection layer RCL may be disposed on the touch sensor layer TCL. The anti-reflection layer RCL may reduce the reflectance of external light incident from outside the display device DD. The anti-reflection layer RCL may include a retarder and a polarizer. Alternatively, the anti-reflection layer RCL may be formed on the touch sensor layer TCL through a continuous process. In this case, the anti-reflection layer RCL may include color filters which selectively transmit light of specific colors and a black matrix disposed between the color filters.

The window member WM may be attached to the anti-reflection layer RCL through an adhesive layer. The window member WM may include a base film including a glass film or a synthetic resin film.

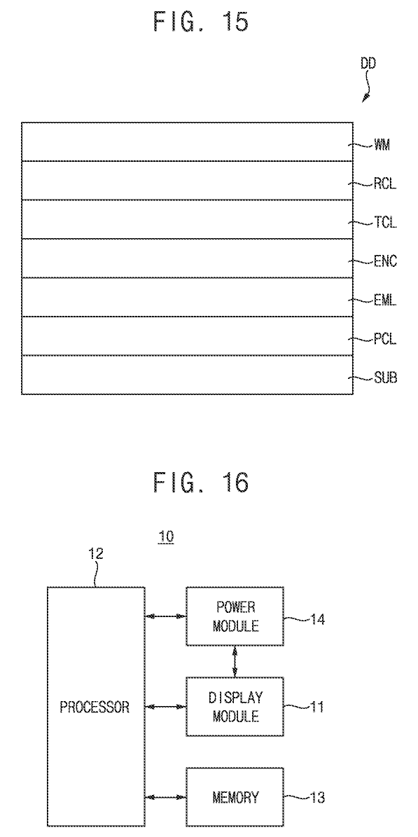

FIG. 16 is a block diagram illustrating an electronic device according to an embodiment.

Referring to FIG. 16, an electronic device 10 according to embodiments of the present disclosure may include a display module 11, a processor 12, a memory 13, and a power module 14.

A display device (e.g., the display device DD of FIG. 15) according to embodiments of the present disclosure may be applied to various electronic devices. The electronic device 10 may include the display device described above, and may further include a module or device having additional functions in addition to the display device.

The processor 12 may include at least one of a central processing unit (CPU), an application processor (AP), a graphic processing unit (GPU), a communication processor (CP), an image signal processor (ISP) and a controller.

The memory 13 may store data information necessary for the operation of the processor 12 or the display module 11. If the processor 12 executes the application stored in the memory 13, an image data signal and/or an input control signal may be transmitted to the display module 11, and the display module 11 may process the received signal and output image information through a display screen.

The power module 14 may include a power supply module, such as a power adapter or a battery device, and a power conversion module which converts the power supplied by the power supply module to generate power required for the operation of the electronic device 10.

At least one of each component of the electronic device 10 described above may be included in the display device according to the above-described embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

As described above, while the present disclosure has been explained with reference to exemplary embodiments, it will be understood by those of ordinary skill in the art that various modifications and changes can be made thereto without departing from the spirit and scope of the invention as defined in the following claims.

The present disclosure may be applied to a process for manufacturing various display devices which can be equipped with a display device. For example, the present disclosure may be applied to high-resolution smartphones, mobile phones, smart pads, smart watches, tablet PCs, vehicle navigation systems, televisions, computer monitors, and notebook computers.

What is claimed is:

1. A cassette transport system comprising:
a cassette including:
a plurality of support bars on which a substrate is loaded;
a plurality of frames defining an open portion and connected to each other;
a filter unit disposed on one of the plurality of frames;
a first input pad and a second input pad electrically connected to the filter unit and disposed in one of the plurality of frames; and
a regulator disposed in one of the plurality of frames and electrically connected to the first input pad and the second input pad;
a shelf including a plurality of support frames on which the cassette is loaded and disposed, and a first output pad disposed on each of the plurality of support frames and which wirelessly supplies power to the first input pad by establishing a wireless coupling with the first input pad when the cassette is loaded on the first output pad; and
a transport apparatus including a second output pad, which transports the cassette and wirelessly supplies power to the second input pad by establishing a wireless coupling with the second input pad when the cassette is loaded or unloaded by the transport apparatus.

2. The cassette transport system of claim 1, wherein, when the cassette is disposed on the plurality of support frames, the first input pad does not directly contact the first output pad.

3. The cassette transport system of claim 1, wherein, when the transport apparatus loads or unloads the cassette, the second input pad does not directly contact the second output pad.

4. The cassette transport system of claim 1, wherein, when the transport apparatus unloads the cassette from the shelf and the cassette moves away from the shelf,
the wireless coupling between the first output pad and the first input pad is turned off and the wireless coupling between the second output pad and the second input pad is maintained, based on a phase difference between a phase of the power applied to the first input pad and a phase of the power applied to the second input pad.

5. The cassette transport system of claim 1, wherein, when the cassette is disposed on the plurality of support frames, the first input pad at least partially overlaps the first output pad in a plan view.

6. The cassette transport system of claim 1, wherein, when the transport apparatus loads or unloads the cassette, the second input pad at least partially overlaps the second output pad in a plan view.

7. The cassette transport system of claim 1, wherein the shelf further includes a shelf frame to which the plurality of support frames is connected and which extends in a height direction, and
when the cassette is disposed on the plurality of support frames, the open portion faces the shelf frame.

8. The cassette transport system of claim 1, wherein the plurality of support frames of the cassette includes:
a first frame;
a second frame facing the first frame;
a third frame connecting the first frame and the second frame;
a fourth frame facing the third frame; and
a fifth frame connecting the first frame, the second frame, the third frame, and the fourth frame.

9. The cassette transport system of claim 8, wherein the filter unit is disposed on the fifth frame.

10. The cassette transport system of claim 8, wherein the first input pad, the second input pad, and the regulator are disposed in the third frame.

11. The cassette transport system of claim 10, wherein a plurality of grooves including a first groove, a second groove, and a third groove are defined in an outer surface of the third frame, and
the first input pad is disposed in the first groove, the second input pad is disposed in the second groove, and the regulator is disposed in the third groove.

12. The cassette transport system of claim 11, wherein the first groove, the second groove, and the third groove are adjacent to the fifth frame.

13. The cassette transport system of claim 11, wherein the first groove overlaps the third groove in a first direction, and
the second groove does not overlap the first groove and the third groove in a second direction interesting the first direction.

14. The cassette transport system of claim 1, wherein the transport apparatus includes:
a main body capable of moving along a rail.
a robot arm, which is connected to the main body to enable to lift and which handles the cassette to load the cassette onto the shelf or unload the cassette from the shelf.

15. The cassette transport system of claim 14, wherein the second output pad is disposed on the robot arm when the cassette is loaded or unloaded by the transport apparatus.

16. A method for transporting a cassette, the method comprising:
loading the cassette on a shelf including a first output pad by a transport apparatus including a second output pad, wherein the cassette includes a plurality of support bars on which a substrate is loaded, a filter unit, a first input pad and a second input pad electrically connected to the filter unit, and a regulator electrically connected to the first input pad and the second input pad; and
unloading the cassette from the shelf by the transport apparatus,
wherein, when the cassette is loaded and disposed onto the shelf, the first output pad wirelessly supplies power to the first input pad by establishing a wireless coupling with the first input pad, and
when the transport apparatus loads or unloads the cassette, the second output pad wirelessly supplies power to the second input pad by establishing a wireless coupling with the second input pad.

17. The method of claim 16, wherein the cassette further includes a plurality of frames defining an open portion and connected to each other, and
the filter unit is disposed on one of the plurality of frames, and the first input pad, the second input pad, and the regulator are disposed in another one of the plurality of frames.

18. The method of claim 16, wherein when the cassette is disposed on the plurality of support frames, the first input pad does not directly contact the first output pad, and
when the transport apparatus loads or unloads the cassette, the second input pad does not directly contact the second output pad.

19. The method of claim 16, wherein when the transport apparatus unloads the cassette from the shelf and the cassette moves away from the shelf,
the wireless coupling between the first output pad and the first input pad is turned off, and the wireless coupling between the second output pad and the second input pad is maintained, based on a phase difference between a phase of the power applied to the first input pad and a phase of the power applied to the second input pad.

20. An electronic device comprising:
a display device including a substrate which is transported and stored by a cassette transport system; and
a processor for transmitting an image data signal and an input control signal to the display device,
wherein the cassette transport system including:
a cassette including:
a plurality of support bars on which the substrate is loaded;
a plurality of frames defining an open portion and connected to each other;
a filter unit disposed on one of the plurality of frames;
a first input pad and a second input pad electrically connected to the filter unit and disposed in one of the plurality of frames; and
a regulator disposed in one of the plurality of frames and electrically connected to the first input pad and the second input pad;
a shelf including a plurality of support frames on which the cassette is loaded and disposed, and a first output pad disposed on each of the plurality of support frames and which wirelessly supplies power to the first input pad by establishing a wireless coupling with the first input pad when the cassette is loaded on the first output pad; and
a transport apparatus including a second output pad which transports the cassette and wirelessly supplies power to the second input pad by establishing a wireless coupling with the second input pad when the cassette is loaded or unloaded by the transport apparatus.
